(19) United States
(12) Patent Application Publication
(10) Pub. No.: US 2007/0262294 A1
(43) Pub. Date: Nov. 15, 2007

(54) Light source including quantum dot material and apparatus including same

(75) Inventors: Steven H. Peterson, Martin, MI (US); Richard B. Bylsma, Ada, MI (US)

Correspondence Address: MCCARTER & ENGLISH , LLP STAMFORD OFFICE, FINANCIAL CENTRE , SUITE 304A, 695 EAST MAIN STREET, STAMFORD, CT, 06901-2138, US

(73) Assignee: X-Rite, Incorporated

(21) Appl. No.: 11/433,991

(22) Filed: May 15, 2006

(51) Int. Cl. H01L 31/00

(52) U.S. Cl. 257/14

(57) ABSTRACT

A light source comprising a light emitting device and quantum dot material is disclosed. According to various embodiments, the quantum dot material is positioned relative to the light emitting device such that the quantum dot material absorbs light emitted from the light emitting device and converts the wavelengths of photons emitted from the light emitting device to longer wavelengths. Judicious selection of the quantum dot material allows the emission spectra of the light source to be tailored to meet the needs of a particular illumination application, and avoids the drawbacks associated with the use of interference filters because the quantum dot material can upconvert the wavelengths emitted from the light emitting device such that the emission spectra of the light source can include wavelengths that are not emitted by the light emitting device itself.

### BACKGROUND

In spectroscopy or color measurement applications which characterize the transmission, absorption, emission or reflection of a target material (such as ink on paper, paint on metal, dyes on cloth, etc.), an illumination source must be present, as well as an apparatus to measure the reflected, transmitted or emitted light. One method for providing the illumination is using light emitted from light emitting diodes (LEDs). To adequately characterize the material properties of the target that would be seen by a human observer, illumination over the entire visible wavelength range from 400 nm to 700 nm is desirable. Individual white or chromatic LEDs and even multiple-LED assemblies, however, often do not provide adequate intensity at all wavelengths in this range.

One known solution for tailoring the emission spectra of a LED to cover the desired illumination range is to use an interference filter with the LED to filter out the unwanted wavelengths. Such an arrangement, however, is not practical where the source (e.g., the LED) does not emit sufficient energy at the desired wavelength. Also, such arrangements can be inefficient for certain applications because much of the energy emissions from the source may be filter out and therefore wasted.

### SUMMARY

In one general aspect, the present invention is directed to a light source comprising a light emitting device and quantum dot material. The quantum dot material is positioned relative to the light emitting device such that the quantum dot material absorbs light emitted from the light emitting device and converts the wavelengths of at least a portion of the photons emitted from the light emitting device to longer wavelengths. Judicious selection of the quantum dot material allows the emission spectra of the light source to be tailored to meet the needs of a particular illumination application, and avoids the drawbacks associated with the use of interference filters because the quantum dot material can upconvert the wavelengths emitted from the light emitting device such that the emission spectra of the light source can include wavelengths that are not emitted by the light emitting device itself.

According to various implementations, the quantum dot material may comprise a host material and a plurality of quantum dot material intra-layers suspended in the host material, wherein the quantum dot material intra-layers have different light absorption/emission characteristics. Also, the quantum dot material may be positioned directly on the light emitting device, or it may be a part of a quantum dot material assembly spaced apart from the light emitting device that comprises (1) an optically transparent substrate and (2) one or more quantum dot material layers. The quantum dot material layer(s) may comprise quantum dot material and the host material, and the assembly is positioned such that light from the light emitting device is absorbed by the quantum dot material layer(s) on the substrate.

In addition, the light emitting device may comprise one or a number of light emitting diodes (LEDs), one or a number of lasers, one or a number of laser diodes, a lamp, or a combination of these light emitting devices.

The quantum dot material may be chosen such that the emission spectra of the light source meets a desired emission spectra profile. For example, the emission spectra profile may correspond to an adopted industry illumination standard, such as an incandescent illumination standard, a daylight illumination standard or a fluorescent illumination standard. Also, the quantum dot material may be chosen such that the emission spectra of the light source may cover a narrow band of wavelengths, for example.

In addition, the light source may comprise (1) a lower lens between the light emitting device and the quantum dot material for collecting and focusing light from the light emitting device onto the quantum dot material and/or (2) an upper lens, wherein the quantum dot material is between the light emitting device and the upper lens, for collecting and focusing light from the quantum dot material on a target sample material.

In another general aspect, the present invention is directed to an apparatus for measuring a spectroscopic property of a target material. The apparatus may comprise, for example, the above-described light source for emitting light photons to impinge upon the target material and an optical radiation sensing device for detecting light reflected by the target material. The apparatus may, of course, comprise other components.

### FIGURES

Various embodiments of the present invention are described herein by way of example in conjunction with the following figures, wherein:

FIGS. 1 and 3-6 are diagrams of a light source according to various embodiments of the present invention;

FIG. 2 is a diagram of the quantum dot material layer according to various embodiments of the present invention; and

FIG. 7 is a block diagram of a spectroscopic apparatus according to various embodiments of the present invention.

### DETAILED DESCRIPTION

FIG. 1 is a diagram of a light source according to various embodiments of the present invention. In the illustrated embodiment, the light source 10 includes a light emitting device 12 mounted on a header 14. In one embodiment, the light emitting device 12 may be a light emitting diode (LED) including a lead wire 16 that allows the LED to be biased so that it will emit light. The LED may emit photons in the ultraviolet and/or visible portions of the optical spectrum. In other embodiments, the light emitting device 12 may be, for example, a laser, a laser diode, multiple LEDs, a lamp, or combinations thereof.

The light source 10 illustrated in FIG. 1 also includes, in the path of the emitted light from the light emitting device 12, an assembly 18 comprising quantum dot material layer 20 placed on a substrate 22. The quantum dot material layer 20 may comprise quantum dot material incorporated in an inert host material, such as epoxy, resin, gel, etc. Quantum dots have the characteristic that by adjusting the size and chemistry of the quantum dot particles, the optical properties of the material, such as light absorption or light emission, can be tailored to meet desired characteristics. For example, quantum dot material, which may be made from CdSe, CdS, ZnS or other materials, may have absorption in the blue and UV portion of the optical spectrum and emission wavelengths in the visible part of the optical spectrum. This allows these materials to be used for a variety of spectroscopic applications which require illumination in the visible spectral region.

In the light source 10 of FIG. 1, the quantum dot material layer 20 may absorb all or part of the light from the light emitting device 12 that impinges on the quantum dot material layer 20. That energy may then be re-emitted at longer wavelengths (i.e., lower energy). That is, the light emitting device 12 may optically pump the quantum dot material layer 20, which may convert at least a portion of the short wavelength photons emitted by the light emitting device 12 into longer wavelength photons. By correctly selecting the quantum dot material, therefore, a desired illumination wavelength can be obtained.

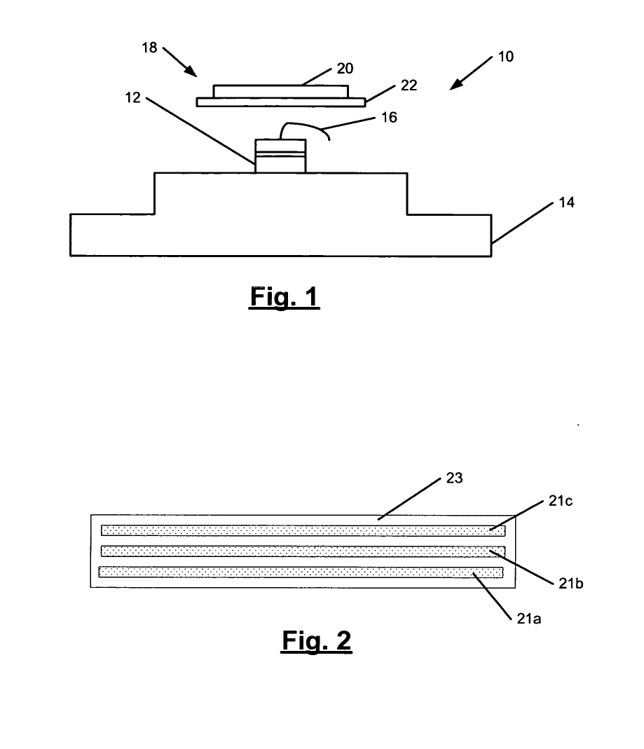

According to various embodiments, the quantum dot material layer 20 may comprise a composite of different quantum dot intra-layers 21a-c suspended in the host material 23, as shown in FIG. 2, each intra-layer 21a-c having different absorption/emission characteristics. For example, the first quantum dot material intra-layer 21a may convert a portion of the light from the light emitting device 12 to a certain, longer wavelength range, and the second quantum dot material intra-layer 21b may convert a portion of that light to an even longer wavelength range, and so on. In another embodiment, the second intra-layer 21b may transmit the longer wavelengths emitted by the first intra-layer 21a, and may also convert another portion of the shorter wavelengths from the light emitting device to a second, higher wavelength, and so on. In addition, the thicknesses of the various quantum dot material intra-layers 21a-c could also be selected to tune the intensity of the emitted light. This may allow the illumination spectra to be further tailored to have specific features, such as multiple sharp emission peaks or broad band illumination that covers a wide range of the optical spectrum. Also, one or more of the intra-layers 21a-c may comprise phosphors rather than quantum dot material according to various embodiments.

The substrate 22 on which the quantum dot material layer 20 is placed may be optically transparent such that all or most of the light from light emitting device 12 passes through the substrate 22 and impinges on the quantum dot material layer 20. According to various embodiments, the substrate 20 may be made from glass, such as sapphire glass. The substrate 22 may be spaced-apart from the light emitting device 12 as shown in FIG. 1 and may be supported by a frame (not shown), for example. The quantum dot assembly 18 and the light emitting device 12 may additionally be encased in a casing (not shown).

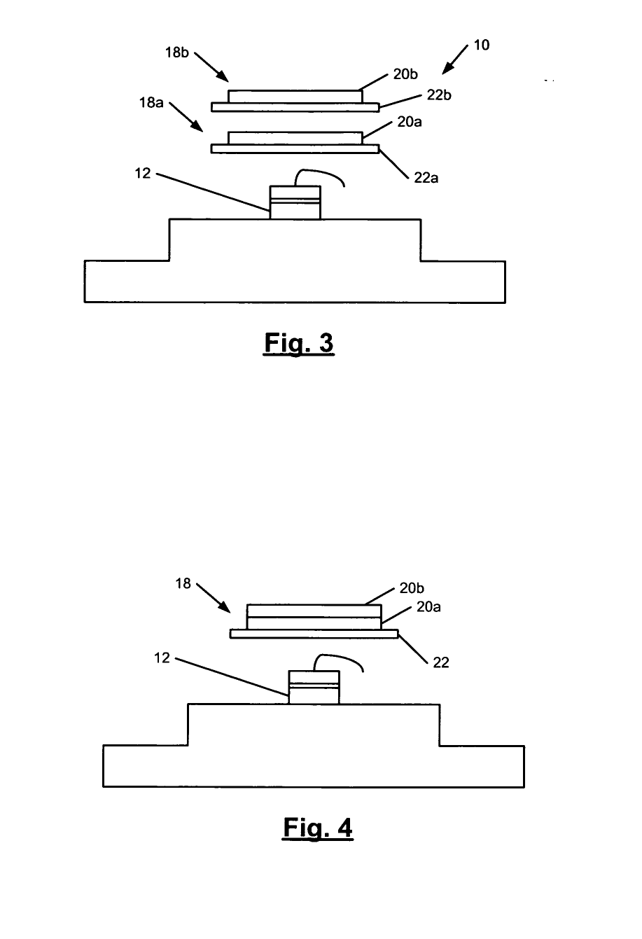

According to various embodiments, the light source 10 may comprise multiple quantum dot assemblies 18. FIG. 3, for example, shows an embodiment of the light source 10 comprising two quantum dot assemblies 18a-b. In such an arrangement, the quantum dot material layer 20a of one of the assemblies 18a may have differently tailored absorption/emission characteristics than the quantum dot material layer 20b of the other assembly 18b. That way, for example, like the embodiment discussed above where multiple quantum dot material intra-layers 21 are suspended in a common host material, the first quantum dot material layer 20a may convert a portion of the light from the light emitting device 12 to a certain, longer wavelength range, and the second quantum dot material layer 20b may convert a portion of that light to an even longer wavelength range, and so on. According to another embodiment, the second quantum dot material layer 20b may transmit the longer wavelengths emitted from the first quantum dot material layer 20a, and convert another portion of the shorter wavelengths emitted from the light emitting device 12 to another, longer wavelength range, which may be longer or shorter than the wavelengths emitted by the first quantum dot material layer 20a, and so on. In this particular embodiment the light emitted from layer 20a will be transmitted through layer 20b, but both layers will absorb light photons emitted from the light emitting device. The thicknesses of the various quantum dot material layers 20a,b could also be selected to tune the intensity of the emitted light. In addition, one or more of the quantum dot material layers 20a,b may comprise a composite of different quantum dot intra-layers or phosphors suspended in the host material, each which different absorption/emission characteristics, as described above in connection with FIG. 2.

In other embodiments, rather than using two (or more) substrates 22a,b as in the embodiment of FIG. 2, the two (or more) quantum dot material layers 20a,b may be applied sequentially to a common substrate 22, as shown in FIG. 4.

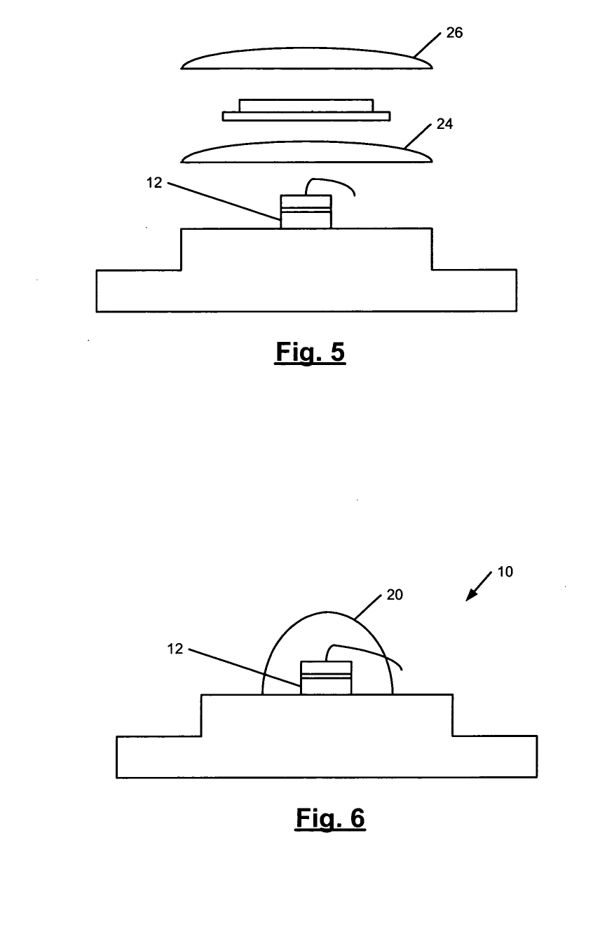

According to other embodiments, as shown in FIG. 5, the light source 10 may include one or more lenses, such as a lens 24 positioned between the light emitting device 12 and the quantum dot material assembly 18 and/or a lens 26 after the quantum dot material assembly 18. The lens 24 may collect and focus light from the light emitting device 12 onto the quantum dot material assembly 18, which may provide more efficient use of the light energy from the light emitting device 12. The lens 26 may collimate the light exiting the quantum dot material assembly 18. Also, the lens 26 may collect and focus light emitted from the quantum dot material on a target sample to be illuminated by the light source 10. This may further enhance the efficiency of the light source 10.

In other embodiments, as shown in FIG. 6, the quantum dot material layer 20 may be applied onto the light emitting device 12, rather than placing it on a substrate as per the embodiments of FIGS. 1-5.

By careful selection of various options, including the characteristics of the quantum dot material layer(s) 20 (including the number and characteristics of the intra-layers 21, if any), the number of quantum dot material layers 20, and the light emission spectral characteristics of the light emitting device 12, a desired emission spectra profile may be produced (or at least approximated). For example, in one embodiment, the light emitting device 12 may emit photons in the ultraviolet portion of the optical spectrum (wavelengths <400 μm), and the quantum dot material assembly 18 may convert the pump light to greater wavelengths at sufficient intensities over a broad spectrum, such as wavelengths of 400 nm to 700 nm. According to another embodiment, the light emitting device 12 may emit photons in the blue portion of the optical spectrum (wavelengths between 400 nm and 425 nm), and the quantum dot material assembly 18 may emit light at sufficient intensities over the 400 nm to 700 nm range.

According to other embodiments, the quantum dot material layer(s) 20 may be chosen such that the emission spectra of the light source 10 is limited to a narrow band of wavelengths. As used herein, “narrow band” means less than or equal to 50 nm full width at half maximum (FWHM). That is, when the emission spectra of the light source 10 is a narrow band, the difference between the wavelengths at which emission intensity of the light source is half the maximum intensity is less than or equal to 50 nm.

According to other embodiments, the quantum dot material layer(s) 20 may be chosen such that the emission spectra of the light source corresponds to a known spectral emission standard such as, for example, incandescent standards (e.g., CIE standard illuminant A), daylight standards (e.g., CIE standard illuminant D65 or D50), fluorescent standards (e.g., CIE standard illuminant F2 or F11), or other defined standards.

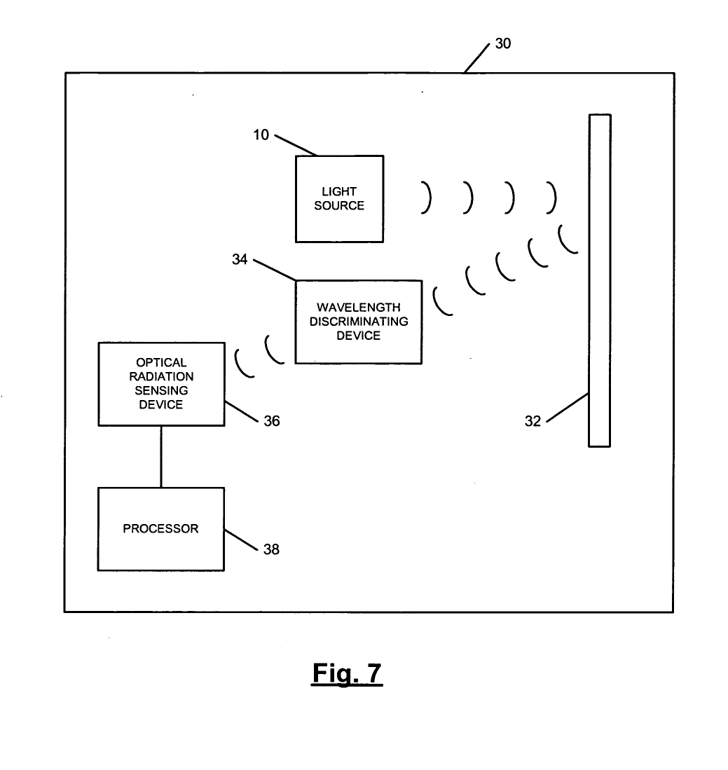

One or more of the light sources 10 described above may be employed, for example, in a color measurement or spectroscopic apparatus to measure the transmission, absorption, emission and/or reflection properties of a material. FIG. 7 is a simplified block diagram of a color measurement or spectroscopic apparatus 30 according to various embodiments of the present invention that comprises one light source 10 for illuminating a target material 32, a wavelength discriminating device 34, and an optical radiation sensing device 36. Reflected light from the target material 32 can be filtered by the wavelength discriminating device 34, which may be, for example, a prism, diffraction grating, holographic grating, or assembly of optical filters. The optical radiation sensing device 36, which may comprise, for example, one or a number of photodiodes, may sense the light from the material 32 passing through the wavelength discriminating device 34. A processor 38 in communication with the optical radiation sensing device 36 may determine the transmission, absorption, emission or reflection of the material 32. Also, the system 30 may include other optical components (not shown), such as refractive or diffractive lenses or mirrors, for either directing light from the light source 10 onto the material 32 and/or directing light from the material 32 to the wavelength discriminating device 34.

One or more of the light sources 10 could be used in other equipment, including, for example, a printing press, an ink jet printer, or other color-based process monitoring equipment.

While several embodiments of the invention have been described, it should be apparent, that various modifications, alterations and adaptations to those embodiments may occur to persons skilled in the art with the attainment of some or all of the advantages of the invention. For example, the materials and the emission spectra profiles described herein are illustrative only. All such modifications, alterations and adaptations are intended to be covered as defined by the appended claims without departing from the scope and spirit of the present invention.

What is claimed is:

1. A light source comprising:
a light emitting device;
quantum dot material positioned to absorb light emitted from the light emitting device and for converting the wavelengths of at least a portion of the photons emitted from the light emitting device to longer wavelengths.

2. The light source of claim 1, wherein the quantum dot material comprises:
a host material; and
a plurality of quantum dot material intra-layers suspended in the host material.

3. The light source of claim 1, wherein the quantum dot material is positioned on the light emitting device.

4. The light source of claim 1, wherein the light emitting device comprises at least one LED.

5. The light source of claim 1, wherein the light emitting device comprises at least one laser.

6. The light source of claim 1, wherein the light emitting device comprises at least one laser diode.

7. The light source of claim 1, wherein the light emitting device comprises a lamp.

8. The light source of claim 1, wherein the light emitting device comprises a combination of one or more LEDs, one or more lasers, or one or more laser diodes.

9. The light source of claim 1, further comprising a quantum dot material assembly, wherein the quantum dot material assembly comprises:
an optically transparent substrate; and
at least one quantum dot material layer located on the substrate and comprising the quantum dot material.

10. The light source of claim 9, wherein the quantum dot material layer comprises:
a host material; and
a plurality of quantum dot material intra-layers suspended in the host material.

11. The light source of claim 10, wherein each of the plurality of quantum dot material intra-layers have different light emission characteristics.

12. The light source of claim 1, further comprising a quantum dot material assembly, wherein the quantum dot material assembly comprises:
an optically transparent substrate;
a first quantum dot material layer located on the substrate and comprising quantum dot material; and
a second quantum dot material layer located on the first quantum dot material layer and comprising quantum dot material, wherein the emission characteristics of the second quantum dot layer are different from the emission characteristics of the first quantum dot material layer.

13. The light source of claim 1, further comprising a plurality of quantum dot material assemblies, wherein each quantum dot material assembly comprises:
an optically transparent substrate; and
at least one quantum dot material layer located on the substrate and comprising quantum dot material

14. The light source of claim 1, wherein the emission spectra of the light source corresponds to an adopted illumination standard.

15. The light source of claim 14, wherein the adopted illumination standard is selected from the group consisting of an incandescent illumination standard, a daylight illumination standard and a fluorescent illumination standard.

16. The light source of claim 1, wherein the emission spectra of the light source is a narrow band of wavelengths.

17. The light source of claim 9, further comprising a lower lens between the light emitting device and the quantum dot material assembly.

18. The light source of claim 17, further comprising an upper lens, such that the quantum dot material assembly is between the light emitting device and the upper lens.

19. The light source of claim 9, further comprising an upper lens, such that the quantum dot material assembly is between the light emitting device and the upper lens.

20. A light source comprising:
a light emitting diode (LED); and
a first quantum dot material assembly comprising:
an optically transparent substrate; and
at least one quantum dot material layer located on the substrate, wherein the first quantum dot material assembly is oriented such that photons from the LED are absorbed by the quantum dot material layer and the quantum dot material layer converts the wavelengths of at least a portion of the photons emitted from the LED to longer wavelengths.

21. The light source of claim 20, wherein the quantum dot material layer comprises:
a host material; and
a plurality of quantum dot material intra-layers suspended in the host material, wherein each of the plurality of quantum dot material intra-layers has different light emission characteristics.

22. The light source of claim 20, wherein the first quantum dot material assembly comprises:
a first quantum dot material layer on the substrate; and
a second quantum dot material layer on the first quantum dot material layer, wherein the first quantum dot material layer has different light emission characteristics than the second quantum dot material layer.

23. The light source of claim 20, further comprising a second quantum dot material assembly, wherein in the first quantum dot material assembly is between the LED and the second quantum dot material assembly, and wherein the second quantum dot material assembly comprises:
a second substrate; and
at least one second quantum dot material layer on the second substrate, wherein the second quantum dot material assembly is oriented such that photons from the first quantum dot assembly are absorbed by the second quantum dot material layer and the second quantum dot material layer converts the wavelengths of at least a portion of the photons emitted from the first quantum dot material layer to longer wavelengths.

24. The light source of claim 20, further comprising a second quantum dot material assembly, wherein in the first quantum dot material assembly is between the LED and the second quantum dot material assembly, and wherein the second quantum dot material assembly comprises:
a second optically transparent substrate; and
at least one second quantum dot material layer on the second substrate, wherein the second quantum dot material layer transmits photons emitted from the first quantum dot material assembly and converts the wavelengths of a second portion of photons emitted from the LED to longer wavelengths.

25. The light source of claim 20, wherein the quantum dot material layer emits light having wavelengths covering the range of 400 nm to 700 nm.

26. The light source of claim 25, wherein the LED emits light having wavelengths less than 400 nm.

27. The light source of claim 25, wherein the LED emits light having wavelengths between 400 nm and 425 nm.

28. The light source of claim 20, wherein the emission spectra of the light source corresponds to an adopted illumination standard.

29. The light source of claim 28, wherein the adopted illumination standard is selected from the group consisting of an incandescent illumination standard, a daylight illumination standard and a fluorescent illumination standard.

30. An apparatus for measuring a spectroscopic property of a target material comprising:
a light source for emitting light photons to impinge upon the target material, the light source comprising:
a light emitting device;
quantum dot material positioned to absorb light emitted from the light emitting device and for converting the wavelengths of photons emitted from the light emitting device to longer wavelengths;
a optical radiation sensing device for detecting light reflected by the target material.

31. The apparatus of claim 30, wherein the quantum dot material comprises:
a host material; and
a plurality of quantum dot material intra-layers suspended in the host material.

32. The apparatus of claim 30, wherein the light emitting device comprises at least one LED.

33. The apparatus of claim 30, wherein the light emitting device comprises a combination of one or more LEDs, one or more lasers, or one or more laser diodes.

34. The apparatus of claim 30, further comprising at least one quantum dot material assembly, wherein the at least one quantum dot material assembly comprises:
an optically transparent substrate; and
at least one quantum dot material layer located on the substrate and comprising the quantum dot material.

35. The apparatus of claim 34, wherein the quantum dot material layer comprises:
a host material; and
a plurality of quantum dot material intra-layers suspended in the host material, wherein each of the plurality of quantum dot material intra-layers have different light emission characteristics.

36. The apparatus of claim 30, wherein the emission spectra of the light source corresponds to an adopted illumination standard.

37. The apparatus of claim 30, wherein the emission spectra of the light source is a narrow band of wavelengths.

38. The apparatus of claim 34, further comprising a lower lens between the light emitting device and the quantum dot material assembly.

39. The apparatus of claim 38, further comprising an upper lens, such that the quantum dot material assembly is between the light emitting device and the upper lens.

40. The apparatus of claim 34, further comprising an upper lens, such that the quantum dot material assembly is between the light emitting device and the upper lens.

41. The apparatus of claim 34, wherein:
the light illuminating device comprises at least one LED; and
the quantum dot material assembly emits light having wavelengths covering the range of 400 nm to 700 nm.

42. The apparatus of claim 41, wherein the LED emits light having wavelengths less than 400 nm.

43. The light source of claim 41, wherein the LED emits light having wavelengths between 400 nm and 425 nm.
